(19) United States
(12) Patent Application Publication
(10) Pub. No.: US 2002/0098618 A1
(43) Pub. Date: Jul. 25, 2002

(54) Method and apparatus for transferring a feature pattern from an inked surface to a substrate

(76) Inventor: John A. Rogers, New Providence, NJ (US)

Correspondence Address: Docket Administrator (Room 3J-219), Lucent Technologies Inc., 101 Crawfords Corner Road, Holmdel, NJ, 07733-3030, US

(21) Appl. No.: 09/966,883

(22) Filed: Sep. 29, 2001

Related U.S. Application Data
(60) Provisional application No. 60/262,821, filed on Jan. 19, 2001.

(51) Int. Cl. H01L 21/44; H01L 21/48; H01L 21/50

(52) U.S. Cl. 438/107; 438/106

(57) ABSTRACT

A feature pattern stamp and a substrate are disclosed with sufficiently high Young's (elastic) moduli that features smaller than 100 μm in at least one lateral dimension are accurately transferred. Such a sufficiently high elastic modulus prevents the deformation of the printed feature pattern on the substrate that occurs when substrates with a lower elastic modulus are used. As the substrate is brought into contact with a stamp with a relatively high elastic modulus and exerts pressure thereupon, the features on the stamp are less able to move relative to one another or to the substrate as compared to when a stamp with lower elastic modulus is used.

### CROSS-REFERENCE

This application claims the benefit of U.S. Provisional Application, Serial No. 06/262821, filed Jan. 19, 2001 and titled “Method for Flexibly Transferring A Feature Pattern From an Inked Surface To A Substrate.”

### FIELD OF THE INVENTION

The present invention is related to transferring a feature pattern from an inked surface to a substrate.

### BACKGROUND OF THE INVENTION

There has been a growing need in many fields for a method of accurately transferring a detailed feature pattern from one surface to another. Such feature patterns may be inked with patterning ink and then transferred from feature pattern stamps to a surface by using a transfer process wherein an inked stamp and the surface are contacted. An example of the use of such transfers is in the production of thin, lightweight electrophoretic displays. Such displays comprise a plane of interconnected transistors on a flexible (e.g., plastic) substrate that is placed underneath a layer of cells filled with electrophoretic display ink. When current is passed through a transistor underneath a specific ink cell, the perceived color of the ink in that cell changes, e.g., from black to white, allowing images to be displayed.

In producing such displays, various feature patterns must be created on various substrates to, for example, define a pattern of resist material that establishes an etch pattern (e.g., for etching the cells to hold ink), define a pattern of transistors, or interconnect the transistors together via conductive material. As the individual features of such feature patterns become smaller and more closely spaced in order to increase the resolution of the electrophoretic display, for example, reducing distortions to those features occurring during the transfer process becomes more critical.

Typical stamps for such applications utilize a material with a high number of pores (e.g., less than a few nanometers in diameter), which hold the patterning ink. This small pore size is required to transfer relatively fine feature details. Additionally, such stamps are highly conformable to surfaces they contact and are thus able to accurately transfer the fine feature details to the surface that is to be printed. A material typically used that exhibits such desired pore size and conformability is polydimethylsiloxane. However, because of the relatively low elastic modulus of polydimethylsiloxane, as the substrate is brought into contact with the stamp, the pressure exerted during the contact causes portions of the stamp feature patterns to shift when in contact with the substrate, thereby distorting the pattern when transferred from the stamp to the substrate. Such distortion can render the transferred feature pattern unusable.

Another problem encountered in transferring feature patterns from a stamp to a substrate is dust adhering to either the stamp or the substrate. If dust particles adhere in sufficient number in critical locations on the stamp or substrate, the ink will not be transferred to the substrate at those locations, resulting in significant defects in the transferred feature pattern. Prior methods of removing dust from the stamp include such measures as directing forced air over the stamp or substrate. Such methods were adequate in the prior art.

Previous methods of transferring a feature pattern can also create defects and distortions resulting from air bubbles trapped between the stamp and the substrate. One typical prior art method, represented in FIG. 1, involves simply lowering the substrate 101 onto the stamp 102 (or vice versa) in an attempt to bring the entire feature pattern 103 on stamp 102 into contact with the substrate at one time. Since air may not be able to escape from all locations between the stamp and the substrate, air bubbles of various sizes may form. As a result, the feature pattern may not transfer to the substrate at the air bubble locations. FIG. 2 shows another prior art method wherein the substrate 201 is brought into contact with one edge 203 of the stamp 202. The raised end of the substrate 201 is then lowered in direction 204 ultimately bringing the feature pattern 205 into contact with the substrate 201. This method can also result in trapped air bubbles.

### SUMMARY OF THE INVENTION

The inventor has recognized that the aforementioned problems related to transferring a feature pattern with extremely small features (e.g., wherein at least one lateral dimension of the features is smaller than 100 μm), from a stamp to a substrate, can be overcome by using a stamp and a substrate with sufficiently high elastic moduli such that features smaller than 100 μm in at least one lateral dimension are accurately transferred. The sufficiency of the magnitude of the elastic moduli of the stamp and the substrate will vary with the size of the feature pattern and individual features thereupon, as well as with the intended use of those features. However, the elastic moduli of the stamp and substrate must be sufficiently high that the features on the substrate remain functionally undistorted by the process of transferring those features to the substrate.

Using stamps and substrates with such elastic moduli prevents the aforementioned deformation of the printed feature pattern on the substrate that occurs when substrates and stamps lacking these properties are used. As the substrate of the present invention is brought into contact with the stamp of the present invention and exerts pressure thereupon, the features on the stamp are less able to move relative to one another or to the substrate than in the prior art. An exemplary stamp with sufficiently high elastic modulus comprises a thin layer (e.g., 1 mm) of polydimethylsiloxane disposed on a surface in a way such that the resulting structure is a composite stamp with a relatively high composite elastic modulus as compared to the layer of polydimethylsiloxane alone. An example of a suitable surface useful for this purpose is the surface of a layer of glass. The resulting composite stamp may be either relatively rigid or flexible. When used in conjunction with a substrate of high elastic modulus, such as a thin sheet of Mylar® material, the feature pattern on the composite stamp is more precisely and accurately printed onto the substrate, allowing, for example, finer feature patterns with smaller details to be transferred accurately. The Mylar material substrate may also be relatively rigid or relatively flexible.

Solutions to the other problems mentioned above are disclosed herein and are the subject of my copending U.S. patent applications Ser. No.______ and Ser. No. ______, titled “Method for Removing Unwanted Particles From a Surface Used in the Process of Flexibly Transferring a Feature Pattern from an Inked Surface to a Substrate,” and “Method for Preventing Distortions in a Flexibly Transferred Feature Pattern,” filed of even date herewith.

### BRIEF DESCRIPTION OF THE DRAWINGS

FIG. 1 shows a prior art method of transferring a feature pattern from a stamp to a substrate wherein the entire pattern is brought into contact with the substrate at one time;

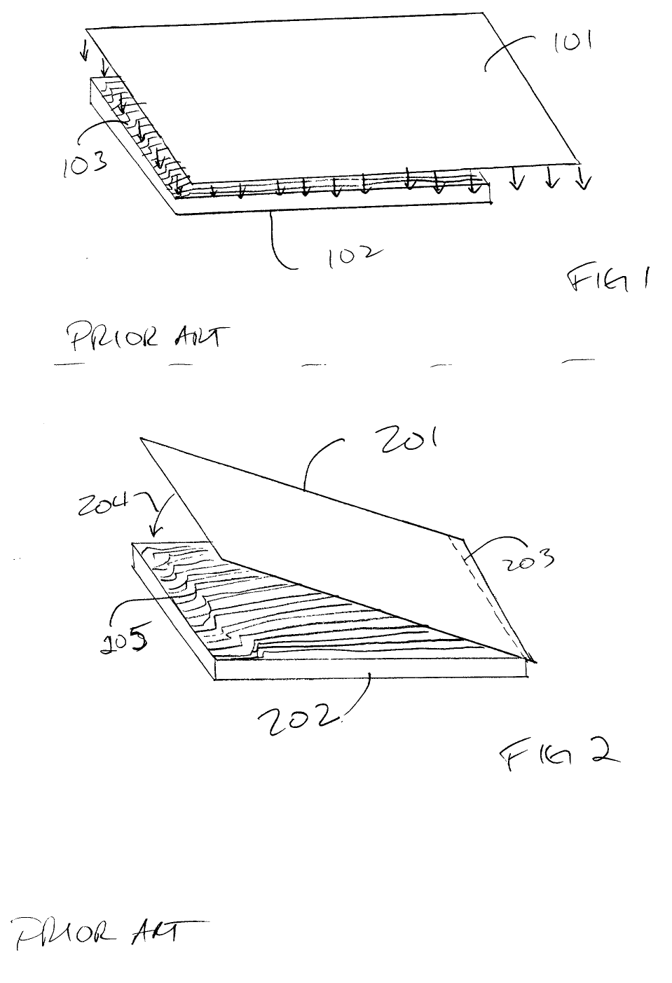

FIG. 2 shows a prior art method of transferring a feature pattern to a substrate wherein the substrate is first brought into contact with one edge of the stamp;

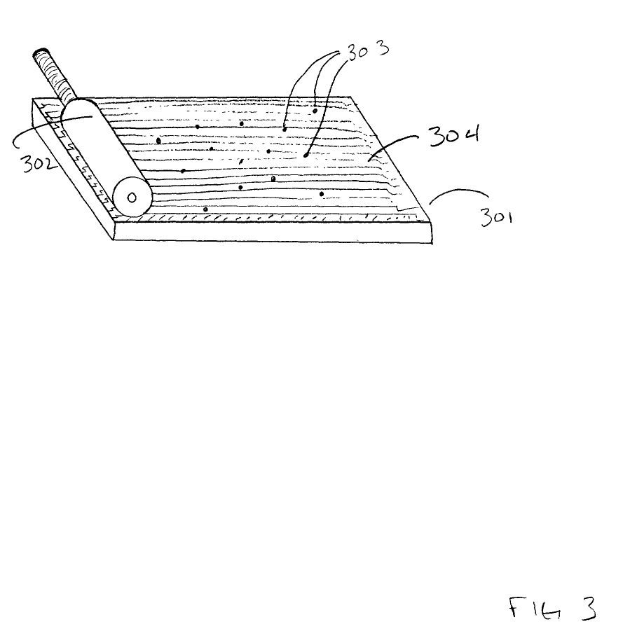

FIG. 3 shows a method of the present invention wherein, before the feature pattern is inked, dust is removed from the stamp;

FIG. 4 shows a method of th e present invention wherein, before a substrate high elastic modulus is brought into contact with a stamp of high elastic modulus, the substrate is flexed into a saddle shape; and

FIG. 5 shows the method of FIG. 4 wherein the substrate of high elastic modulus is progressively unflexed in such a way that a line of contact advances across the surface of the stamp with high elastic modulus.

### DETAILED DESCRIPTION OF THE INVENTION

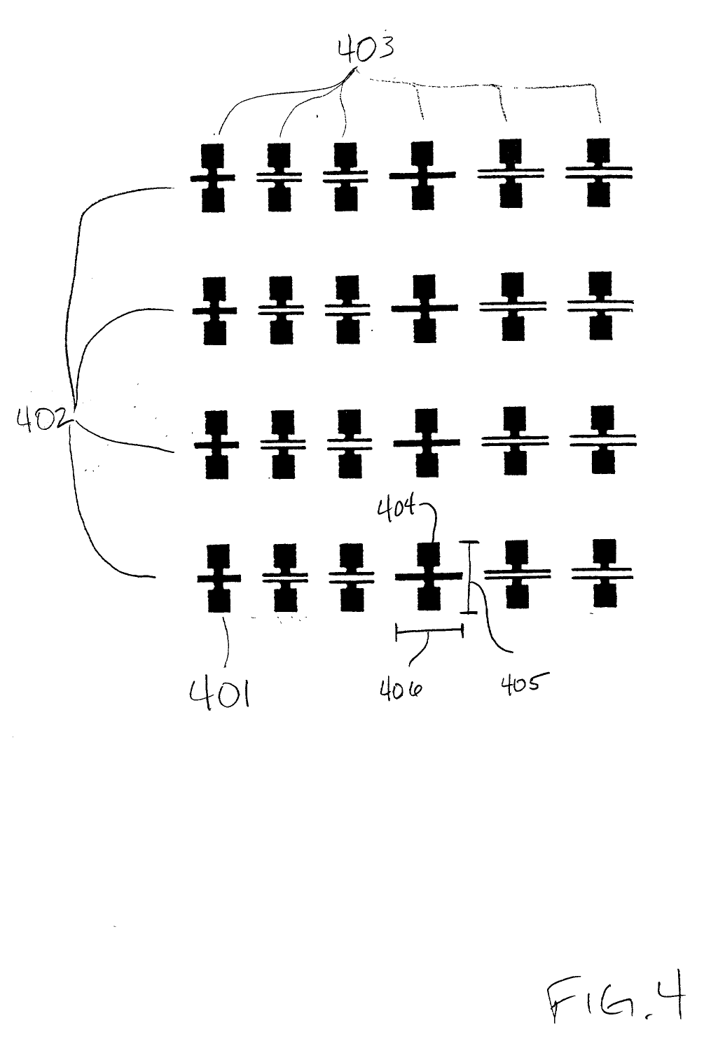

FIG. 3 shows an embodiment in accordance with the invention set forth in the above cited patent application, titled “Method for Removing Unwanted Particles From a Surface Used in the Process of Flexibly Transferring a Feature Pattern from an Inked Surface to a Substrate,” wherein, prior to transferring ink from the feature pattern 304 on stamp 303 to the substrate 301, dust 303 is removed from the stamp. To remove the dust from feature pattern 304, roller 302 is rolled over stamp 301. Roller 302 is, for example, an adhesive-tape lint remover. However, any adhesive surface that can remove dust and other particles in a similar manner is suitable. Dust 303 adheres to the surface of the roller 302 and is thus removed from stamp 301. A similar procedure can be used to remove dust particles from the substrate.

Feature pattern 304 is illustrated for simplicity as a series of regularly spaced parallel features. However, feature patterns of various complexities may also be used. Features on the feature pattern, as used herein, are defined as those individual elements of the feature pattern that are intended to be transferred to the substrate and result in a functional part of the transferred feature pattern.

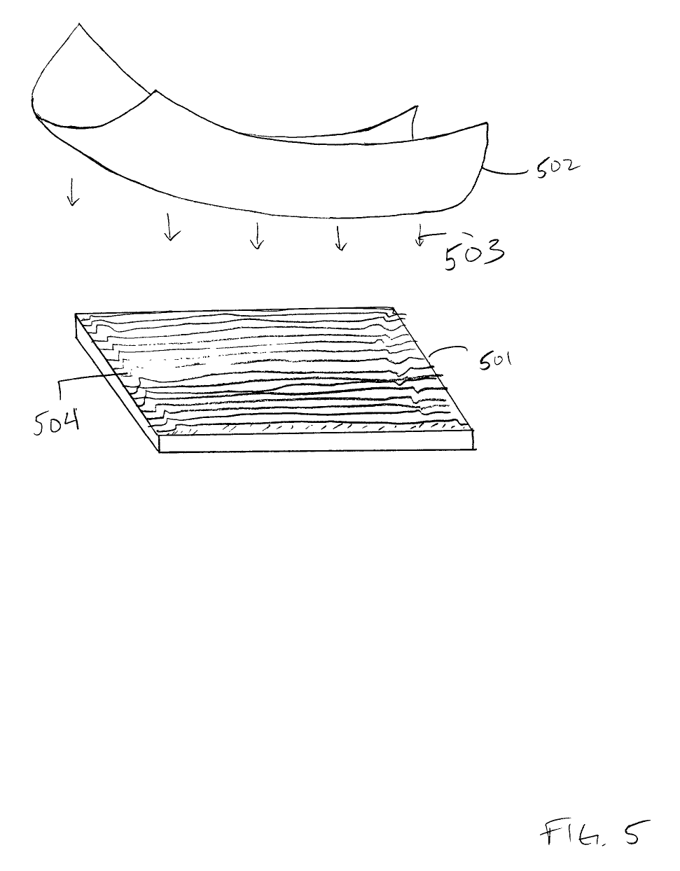

FIG. 4 shows an embodiment in accordance with the present invention wherein the features on the feature pattern stamp (or a portion of the stamp) are parts of individual transistors arranged in a grid with rows 402 and columns 403. Many other arrangements of the features other than a grid are possible. Illustratively, each transistor in the grid of FIG. 4, such as transistor 404, has, among other dimensions, lateral dimensions such as length 405 and width 406. The method of the present invention is suitable for use with the features of FIG. 4, even when those features are very small, e.g., where at least one of lateral dimensions 405 and 406 is less than 100 μm.

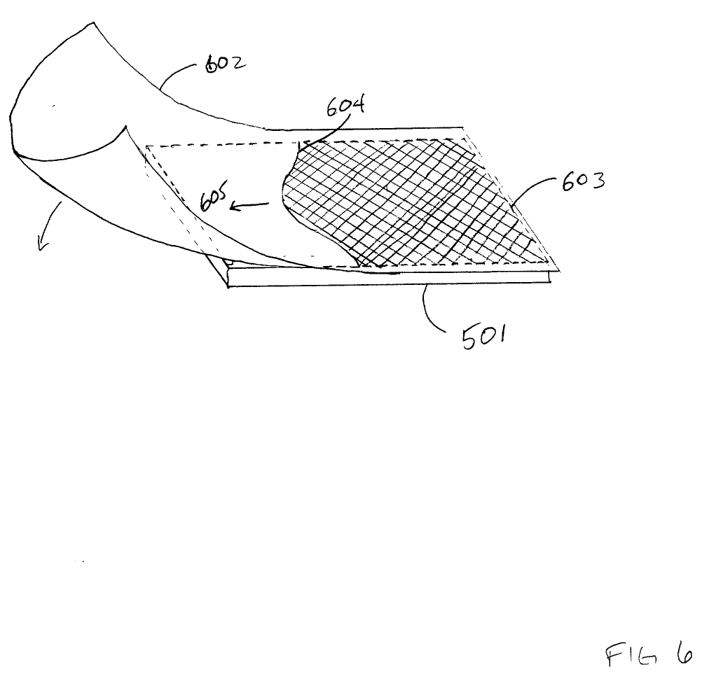

FIG. 5 shows an embodiment in accordance with the present invention wherein the substrate 502 to be imprinted with the feature pattern on stamp 501 is flexed prior to being lowered in direction 503 to make contact with feature pattern 504. Illustratively, the features on stamp 501 are smaller than 100 μm in at least one lateral dimension. The substrate 502 is flexed axially to form a cylindrical, or approximately cylindrical, surface that is convex toward the stamp. It is beneficial to slightly raise the side edges of the substrate, thereby introducing a slight saddle shape, i.e., a very small additional convexity of the substrate toward the stamp that runs perpendicular to the main convexity. An alternate method of applying the substrate to the feature pattern on the stamp would be to wrap the substrate around a cylindrical roller and roll the substrate across the feature pattern. An exemplary substrate useful in producing electrophoretic displays is a sheet of Mylar® material overcoated with desired layers, such as a layer of the material to be patterned by etching.

One advantageous feature of Mylar material is that it has a relatively high Young's modulus and also has a low flexural rigidity in the dimensions used herein (e.g., a thin substrate) such that the material can be flexed relatively easily. Young's modulus, also known as the elastic modulus, describes the elasticity of a material. A material, such as Mylar material, with a high Young's modulus can be flexed with less distortion to the features on the surface of the material than a material with a low Young's modulus. Flexural rigidity defines the resistance of a material to flexing. A material with relatively low flexural rigidity, such as thin substrate of Mylar material, can be flexed with relative ease.

As a consequence of the aforementioned high elastic modulus and low flexural rigidity, features on the pattern-receiving surface of a Mylar material substrate are not substantially distorted during flexure of the substrate. If a substrate with a low elastic modulus is flexed in this manner to facilitate the transfer of a feature pattern, the feature pattern would be distorted during the pattern transfer process. In the case of the substrate 502, flexing the substrate will not substantially distort the feature pattern during the pattern transfer process.

The hereinabove described transfer of a feature pattern can also be accomplished by flexing a stamp (rather than the substrate) and then contacting the stamp and the substrate. This can be accomplished by reversing flexural rigidity properties of the stamp and the substrate, i.e., so the stamp has a low flexural rigidity relative to the substrate. Thus, the same transfer method described hereinabove may be affected by flexing the stamp in a saddle or other shape, or the stamp may be applied to a cylindrical roller and rolled over a relatively rigid substrate.

FIG. 6 shows an embodiment in accordance with the present invention wherein the substrate 602 is brought into contact with the feature pattern 504 in FIG. 5 on stamp 501 in an advantageous manner. After the substrate 602 has been flexed into a saddle shape as described above, it is brought into contact with at least one point along edge 603 of the inked surface of the stamp and is then partially unflexed to create a line of contact with edge 603. The substrate is then permitted to flatten progressively across the stamp surface. The flexural rigidity of stamp 501 may advantageously be higher than the substrate 602. Flexural rigidity is a function of both the Young's (elastic) modulus and the physical dimensions of a material and is related to how easily that material is flexed. By having a stamp 501 with significantly high elastic modulus it will not distort when the substrate is brought into contact with the feature pattern 504 in FIG. 5. Thus, the features on the stamp 501 will not shift and will be transferred accurately to the substrate 602.

A line of contact 604 between the substrate 602 and the stamp 501 advances across the stamp surface in direction 605, with full contact between the substrate and the stamp being achieved at all points behind the advancing line of contact 604. A similar procedure is used in the case where the stamp is flexed, with the roles of the stamp and the substrate, as used in the procedure described hereinabove, being reversed.

The foregoing merely illustrates the principles of the invention. It will thus be appreciated that those skilled in the art will be able to devise various arrangements that, although not explicitly described or shown herein, embody the principles of the invention and are within its spirit and scope. For example, while the embodiments disclosed above show either the stamp or the substrate having a low flexural rigidity and being unflexed after being brought into contact with a relatively higher flexural rigidity surface, both may in fact have a relatively low flexural rigidity. This would allow, for instance, both the stamp and the substrate to be formed in a cylinder and brought into contact with each other. By then rolling the cylinders as they remained in contact, the feature pattern would be transferred to the substrate. Any use of the hereinabove fine-feature printing method wherein at least one of the stamp and the substrate are of relatively low flexural rigidity is intended to be encompassed by the present invention.

Additionally, in the embodiments described hereinabove, flexing the stamp or substrate is described as a method of contacting a portion of the stamp and a portion of the substrate. In these described methods, the line of contact is progressively advanced across the stamp from one side to the other. However, other methods of bringing about such advancing contact are conceivable. For example, the stamp (or, alternatively, the substrate) may be flexed in a convex manner such that the center portion of the stamp (substrate) contacts the center portion of the substrate (stamp). By then progressively flattening the stamp (substrate), the area of contact between the stamp and the substrate would grow larger by progressively radiating in all or some directions from the center of the substrate (stamp) along the surface of the substrate (stamp). Any such method of flexing either the stamp or substrate and bringing about such advancing contact is intended to be encompassed by the present invention.

Furthermore, all examples and conditional language recited herein are intended expressly to be only for pedagogical purposes to aid the reader in understanding the principles of the invention and are to be construed as being without limitation to such specifically recited examples and conditions. Diagrams herein represent conceptual views of feature pattern stamps and substrates used for the purposes of transferring those feature patterns to the substrate. Diagrams are not necessarily shown to scale but are, instead, merely representative of possible physical arrangements of the components represented therein.

What is claimed is

1. A method for use in the manufacture of an electronic system, said method comprising:
contacting a substrate and the features on a feature pattern stamp, at least one of said features having at least one lateral dimension of less than 100 μm; and
transferring features from said feature pattern stamp to said substrate;
the elastic modulus of said stamp and the elastic modulus of said substrate each being sufficiently high such that said features having at least one lateral dimension of less than 100 μm are accurately transferred to said substrate.

2. The method of claim 1 wherein said feature pattern stamp comprises a layer of polydimethylsiloxane disposed on a glass surface.

3. The method of claim 1 wherein said substrate comprises a sheet of Mylar material.
